(19) United States
(12) Patent Application Publication
(10) Pub. No.: US 2025/0251420 A1
(43) Pub. Date: Aug. 7, 2025

(54) METHOD FOR INSPECTING SEMICONDUCTOR MANUFACTURING EQUIPMENT USING A WAFER

(71) Applicant: SAMSUNG ELECTRONICS CO., LTD., SUWON-SI (KR)

(72) Inventors: Kang Hyun KIM, Suwon-si (KR); Seong Hyeon KIM, Suwon-si (KR); Kyoung Whan OH, Suwon-si (KR); Jeong Gil KIM, Suwon-si (KR)

(21) Appl. No.: 18/970,771

(22) Filed: Dec. 5, 2024

(30) Foreign Application Priority Data
Feb. 1, 2024 (KR) 10-2024-0015863

(51) Int. Cl. G01Q 30/02; G01N 15/14; G01Q 60/24; H01L 21/66

(52) U.S. Cl. CPC G01Q 30/02; G01N 15/14; G01Q 60/24; H01L 22/12

(57) ABSTRACT

Method for inspecting semiconductor manufacturing equipment using wafer is provided. The method comprising introducing the wafer into the semiconductor manufacturing equipment, passing the wafer through at least one wafer processing step inside the semiconductor manufacturing equipment, wherein particles generated by the at least one wafer processing step are collected on the wafer, and inspecting the particles collected on the wafer with an atomic force microscope (AFM), wherein the inspecting of the particles collected on the wafer with the AFM includes irradiating infrared light to the particles collected on the wafer using an infrared ray (IR) source to identify the particles.

### CROSS-REFERENCE TO RELATED APPLICATION

This application claims priority under 35 U.S.C. § 119 to Korean Patent Application No. 10-2024-0015863 filed on Feb. 1, 2024, in the Korean Intellectual Property Office, the disclosure of which is herein incorporated by reference in its entirety.

### BACKGROUND

### 1. Technical Field

The present disclosure relates to a method for inspecting a semiconductor manufacturing equipment using a wafer.

### 2. Discussion of Related Art

A semiconductor processing facility may include a plurality of devices to perform different processes on a wafer. When processing the wafer inside the semiconductor process facility, friction may occur between components of the devices. When friction occurs between the components of the devices, some components may be partially worn and particles generated by the friction may be scattered. The scattered particles settle on the wafer during or after one or more processes. In this way, the particles settled on the wafer may act as a factor reducing a yield of the wafer. Therefore, a lifespan of the components and/or devices inside the facility may be periodically managed.

### SUMMARY

Aspects of the present disclosure provide a method for inspecting a semiconductor manufacturing equipment using a wafer that may increase a semiconductor manufacturing yield.

Aspects of the present disclosure provide a method for inspecting a semiconductor manufacturing equipment using a wafer, wherein an inspection tool may be used in a further processing of the wafer.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a method for inspecting a semiconductor manufacturing equipment using a wafer, the method comprising introducing the wafer into the semiconductor manufacturing equipment, passing the wafer through at least one wafer processing step inside the semiconductor manufacturing equipment, wherein particles generated by the at least one wafer processing step are collected on the wafer, and inspecting the particles collected on the wafer with an atomic force microscope (AFM), wherein the inspecting of the particles collected on the wafer with the AFM includes irradiating infrared light to the particles collected on the wafer using an infrared ray (IR) source to identify the particles.

According to an aspect of the present disclosure, there is provided a method for inspecting a semiconductor manufacturing equipment using a wafer, the method comprising performing a first process on each of a plurality of wafers using any one of a plurality of first process equipment, then performing a second process different from the first process on each of the plurality of wafers using any one of a plurality of second process equipment different than the plurality of first process equipment, wherein a particle generated by at least one of the first process and the second process is collected on a first wafer of the plurality of wafers, and inspecting the particle collected on the first wafer on which the second process has been completed with an atomic force microscope (AFM), wherein the inspecting of the particle collected on the first wafer with the AFM includes irradiating infrared light to the particle collected on the first wafer using an infrared ray (IR) source, and localizing a source of the particle to one of the first process or the second process based on the inspection of the particle.

According to an aspect of the present disclosure, there is provided a method for inspecting a semiconductor manufacturing equipment using a wafer, the method comprising introducing the wafer into an extreme ultraviolet (EUV) exposure equipment, wherein a particle is generated by the EUV exposure equipment, collecting the particle on the wafer while passing through at least one wafer processing step among the plurality of wafer processing steps inside the EUV exposure equipment, and inspecting the particle collected on the wafer with an atomic force microscope (AFM), wherein the plurality of wafer processing steps inside the EUV exposure equipment include transferring the wafer in an atmospheric pressure environment, transferring the wafer using a load lock chamber, transferring the wafer in a vacuum environment, and performing an exposure process on the wafer, and the inspecting of the particle collected on the wafer with the AFM includes irradiating infrared light to the particle collected on the wafer using an infrared ray (IR) source to identify the particle.

It should be noted that the effects of the present disclosure are not limited to those described above, and other effects of the present disclosure will be apparent from the following description. Specific details of other embodiments are included in the detailed description and drawings.

### BRIEF DESCRIPTION OF THE DRAWINGS

The above and other aspects and features of the present disclosure will become more apparent by describing in detail example embodiments thereof with reference to the attached drawings, in which:

FIG. 1 is a flowchart for describing a method for inspecting a semiconductor manufacturing equipment using a wafer according to some example embodiments.

FIG. 2 is an example view for describing the method of FIG. 1

FIG. 3 is an example view for describing an AFM-IR equipment.

FIG. 4 is a partial enlarged view of section I of FIG. 3.

FIG. 5 is an example view for describing an EUV exposure equipment.

FIG. 6 is an enlarged view of section II of FIG. 5.

FIG. 7 is an example view for describing a plurality of areas of the EUV exposure equipment of FIG. 5.

FIG. 8 is an example diagram for describing a photoresist application and soft bake process using a semiconductor spinner equipment.

FIG. 9 is a flowchart for describing a method for inspecting a semiconductor manufacturing equipment using a wafer according to some other example embodiments.

FIG. 10 is an example view for describing the method of FIG. 9.

FIG. 11 and FIG. 12 are example views for describing measuring a level difference of a photoresist using an AFM-IR equipment and irradiating infrared light to the photoresist.

FIG. 13 is a view for describing a method for inspecting a semiconductor manufacturing equipment using a wafer according to still some other example embodiments.

FIG. 14 is a flowchart for describing a method for inspecting a semiconductor manufacturing equipment using a wafer according to still some other example embodiments.

FIG. 15 is a flowchart for describing a method for inspecting a semiconductor manufacturing equipment using a wafer according to still some other example embodiments.

FIG. 16 is an example view for describing the method of FIG. 15.

### DETAILED DESCRIPTION

Hereinafter, a method for inspecting a semiconductor manufacturing equipment using a wafer according to some example embodiments will be described with reference to the accompanying drawings.

The inventive concepts may be implemented in various modifications and have various forms, and specific embodiments are illustrated in the drawings and described in detail in the text. It is to be understood, however, that the inventive concepts are not intended to be limited to the particular forms disclosed, but on the contrary, is intended to cover all modifications, equivalents, and alternatives falling within the spirit and scope of the inventive concepts.

Like reference numerals or symbols refer to like elements throughout. In the drawings, the thickness, the ratio, and the dimension of an element may be exaggerated for effective description of the technical contents.

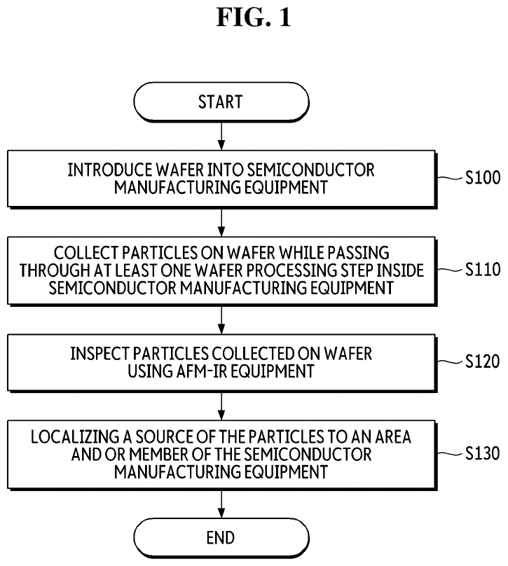

FIG. 1 is a flowchart for describing a method for inspecting a semiconductor manufacturing equipment using a wafer according to some example embodiments.

Referring to FIG. 1, a wafer may be introduced into a semiconductor manufacturing equipment (S100). In this case, the semiconductor manufacturing equipment may be used for manufacturing a semiconductor device by performing a semiconductor manufacturing process on the wafer. For example, the semiconductor manufacturing equipment may include one or more of chemical mechanical polishing (CMP) equipment, etching equipment, or deposition equipment. Further, the semiconductor manufacturing equipment may be photolithography equipment such as an extreme ultraviolet (EUV) scanner. The types of semiconductor manufacturing equipment are not limited to the above-mentioned equipment, and in the description, the semiconductor manufacturing equipment may encompass various types of equipment that may be used to process the wafer.

In some example embodiments, the wafer introduced into the semiconductor manufacturing equipment may be a wafer for manufacturing a semiconductor device. Alternatively, in some example embodiments, the wafer introduced into the semiconductor manufacturing equipment may be a test wafer for detecting and/or inspecting a defect in the semiconductor manufacturing equipment. As such, if the wafer introduced into the semiconductor manufacturing equipment is a test wafer, the test wafer may be used to detect and/or inspect a defect in the semiconductor manufacturing equipment and may not be used to manufacture a semiconductor device.

In some example embodiments, a test wafer may be into the semiconductor manufacturing equipment in response to a determination that a particle on a production wafer includes a same material as a member included in the wafer processing equipment that performed a process on the production wafer. That is, a test wafer may be used to search for a member that may be worn or subject to wear during processing of the production wafer.

Particles may be collected on the wafer while passing through at least one wafer processing step inside the semiconductor manufacturing equipment (S110). For example, it should be understood that step S110 includes generating the particles while passing through at least one wafer processing step inside the semiconductor manufacturing equipment. The wafer introduced into the semiconductor manufacturing equipment may pass through at least one wafer processing step. For example, the semiconductor manufacturing equipment may perform a plurality of wafer processing steps on the wafer. In some example embodiments, when the wafer is a production wafer for manufacturing of the semiconductor device, particles may be collected on the production wafer while the production wafer passes through the wafer processing steps inside the semiconductor manufacturing equipment.

In some example embodiments, when the wafer is a test wafer, particles may be collected on the test wafer while the test wafer passes through one or more of the wafer processing steps inside the semiconductor manufacturing equipment. For example, the test wafer may be used in less than all of the wafer processing steps that may be used for processing a productive wafer.

Particles collected on the wafer may be inspected (S120). The particles may be inspected using atomic force microscope-infrared spectroscopy (AFM-IR) equipment. The particles collected on the wafer may be generated during a processing of the wafer inside the semiconductor manufacturing equipment. For example, the semiconductor manufacturing equipment may include a plurality of members for processing the wafer. In processing the wafer, friction may occur between the plurality of members, which may cause wear to the members and may generate particles. The particles generated inside the semiconductor manufacturing equipment may scatter, and the scattered particles may float in an internal space of the semiconductor manufacturing equipment and settle on the wafer.

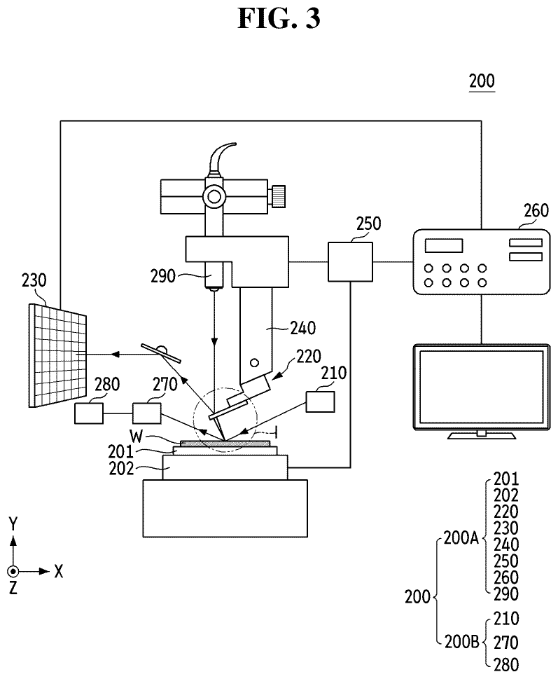

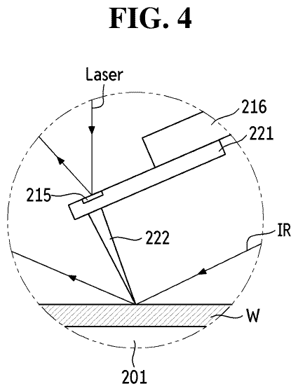

As described herein, the particles collected on the wafer may include portions of the material constituting the members released due to friction and/or wear. When analyzing a molecular structure of the particles collected on the wafer using AFM-IR, it may be possible to identify which of the members inside the semiconductor manufacturing equipment is associated with the friction and/or wear (S130). Similarly, it may be possible to identify an area inside the semiconductor manufacturing equipment associated with the friction and/or wear (S130). For example, in some embodiments, step S130 may include providing a map of materials to members inside the semiconductor manufacturing equipment, but example embodiments are not limited thereto. For example, in some embodiments, step S130 may include providing a map of materials to areas inside the semiconductor manufacturing equipment. In some other embodiments, step S130 may include providing a map of materials to areas inside the semiconductor manufacturing equipment and members insides the areas. A method for inspecting particles using the AFM-IR equipment is described herein with reference to FIG. 3 and FIG. 4.

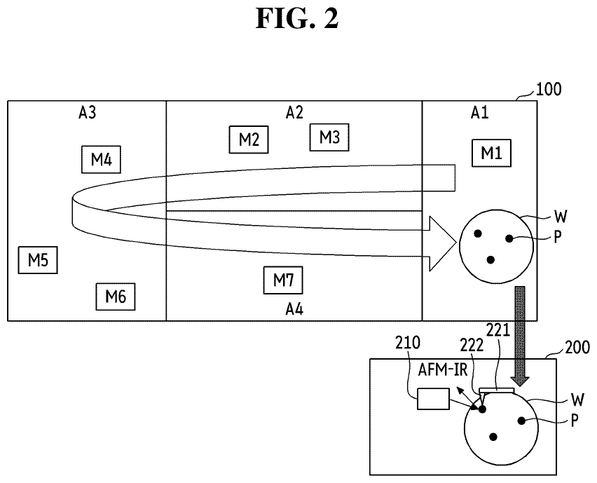

FIG. 2 is an example view for describing the method of FIG. 1.

Referring to FIG. 2, the semiconductor manufacturing equipment 100 may be divided into a plurality of areas. The plurality of areas may include a first area A1, a second area A2, a third area A3, and a fourth area A4. Each of the plurality of areas A1 to A4 may include one or more members. For example, the first area A1 may include a first member M1, and the second area A2 may include a second member and a third member M3. In addition, the third area A3 may include a fourth M4, a fifth member M5, and a sixth member M6, and the fourth area A4 may include a seventh member M7. The members may be different wafer processing equipment.

One or more processes may be performed in one or more of the areas A1 to A4 of the semiconductor manufacturing equipment 100 for processing a wafer. For example, a wafer W may be introduced into the semiconductor manufacturing equipment 100, and processing the wafer using the first member M1 in the first area A1, processing the wafer using the second and third members M2 and M3 in the second area A2, processing the wafer using the fourth, fifth, and sixth members M4, M5, and M6 in the third area A3, and processing the wafer using the seventh member M7 in the fourth area A4.

Internal areas of the semiconductor manufacturing equipment 100 may be divided according to the type of material constituting the members included in each of the areas. For example, the internal area of the semiconductor manufacturing equipment 100 may be divided depending on whether it includes two or more members including the same material. That is, different members including the same material may be divided into different areas. In addition, two or more members included in the same area may include different materials.

For example, as illustrated in FIG. 2, when the first area A1 includes the first member M1 and the second area A2 includes the second and third members M2 and M3, the material included in the first member M1 may be the same as the material included in the second member M2 or may be the same as the material included in the third member M3. Alternatively, the material included in the member M1 may be the same as the material included in the member M2, and may be the same as the material included in the third member M3. In addition, the second and third members M2 and M3 included in the second area A2 may include different materials. In addition, all of the fourth, fifth, and sixth members M4, M5, and M6 included in the third area A3 may include different materials.

In this way, two or more members included in the same area inside the semiconductor manufacturing equipment 100 may include different materials. When two or more members included in the same area inside the semiconductor manufacturing equipment 100 include different materials, and when particles that collected on a wafer while processing the wafer in the same area, a source of the particles may be identified according to the collected particles. For example, a molecular structure of the particles may be identified, and the molecular structure may correspond to a material of a member of the two or more members. The molecular structure of the particles may be used as an indicia of the source of the particles, which may be a member within an area of the semiconductor manufacturing equipment 100. For example, the particles may be localized to an area of the semiconductor manufacturing equipment 100 according to an analysis of the particles.

The source of each particles may be identified in a case where members that do not include the same material are grouped into a same area. The molecular structure of the particles may be identified using the AFM-IR equipment 200. When the molecular structure of the particles is identified using the AFM-IR equipment 200, an inspection time and wafer usage for inspection may be reduced.

In some example embodiments, when the wafer W is the production wafer for actually manufacturing the semiconductor device, the wafer W may pass through the steps of processing the wafer in the first area A1, processing the wafer in the second area A2, processing the wafer in the third area A3, and processing the wafer in the fourth area A4.

In this way, the wafer on which the particles are collected while passing through the areas A1 to A4 of the semiconductor manufacturing equipment 100 may be introduced into the AFM-IR equipment 200. Thereafter, the molecular structure of the particles collected on the wafer W may be analyzed using the AFM-IR equipment 200.

In some other example embodiments, collected particles may be aggregated by subjecting the wafer W to multiple iterations of one or more processes is less than all of the areas A1 to A4. For example, the wafer W may be repeatedly processed in the first area A1 and the second area A2, and may not be processed in another area. A process or processes may be repeatedly performed two or more times, for example, several to dozens of times, and the collected particles may be aggregated over the multiple iterations. In an example analysis in which the number of particles collected on the wafer W when the wafer W is processed in the first, second, and third areas A1, A2, and A3 is greater than the number of particles collected on the wafer W when the wafer W passes through only the first and second areas A1 and A2 may indicate that the particles are mainly generated when the wafer W passes through the third area A3. Here, it may be assumed that the generation of particles during a process corresponds to the number of particles collected on the wafer attributable to the process. In an example, particles may be aggregated by processing the wafer W several to dozens of times between the fourth, fifth, and sixth members M4, M5, and M6 in the third area A3, and the wafer on which the particles are collected in this way may be introduced into the AFM-IR equipment 200 to analyze the molecular structure of the particles.

FIG. 2 illustrates that the semiconductor manufacturing equipment 100 may be divided into the first to fourth areas A1 to A4, but example embodiments are not limited thereto. In addition, the number of members included in each of the areas illustrated in FIG. 2 is an example, and the number of members included in each of the areas of the semiconductor manufacturing equipment 100 may vary depending on an implementation.

FIG. 3 is an example view for describing an AFM-IR equipment. FIG. 4 is a partial enlarged view of section I of FIG. 3.

Referring to FIG. 3 and FIG. 4, the AFM-IR equipment 200 may include AFM equipment 200A and IR equipment 200B. The AFM equipment 200A may include a support unit 201, a measurement unit 220, a light source unit 290, a sensing unit 230, a driving unit 250, a determination unit 260, and a coarse stage 202. The AFM equipment 200A may sense a surface of the wafer W. For example, the AFM equipment 200A may sense the surface of the wafer W with sensitivity at a level of individual atoms on the surface of the wafer W. The AFM equipment 200A may inspect the surface of the wafer W by detecting the van der Waals force or electrostatic force between a probe tip 222 and the wafer W. The AFM equipment 200A may inspect the wafer W by raster scanning the probe tip 222 on the surface of the wafer W. For example, the AFM equipment 200A may inspect the wafer W by a horizontal raster scan of the probe tip 222 on the surface of the wafer W.

In FIG. 3 and FIG. 4 the thicknesses and the dimensions of the elements may be exaggerated for effective description of the technical contents. In particularly, a size of the probe tip 222 may be exaggerated. A length of the probe tip 222 may range from several nanometers (nm) to hundreds of nm.

The AFM equipment 200A may be any one of a contact AFM, a Force Modulus Microscope (FMM), a Lateral Force Microscope (LFM), a Scanning Capacitance Microscope (SCM), a Scanning Thermal Microscope (SThM), a non-contact AFM, Conductive (C) AFM, a Dynamic force Microscope (DFM), an Electrostatic Force Microscope (EFM), a Kelvin Probe Force Microscope (KPFM), a Magnetic Force Microscope (MFM), a Piezoelectric Force Microscope (PFM), or a dynamic contact AFM.

The AFM equipment 200A may operate in a contact mode, a non-contact mode, or a tapping mode. When the AFM equipment 200A operates in the contact mode, a distance between the probe tip 222 and the surface of the wafer W may be several angstroms. At the distance of several angstroms, a repulsive force may be dominant between the probe tip 222 and the surface of the wafer W. In the contact mode, the probe tip 222 may be a soft probe tip, which may reduce or prevent damage to the wafer W. Since a change in force applied to the probe tip 222 may be large depending on a change in the distance between the probe tip 222 and the surface of the wafer W in a repulsive force territory, the surface of the wafer W may be inspected with high resolution.

When the AFM equipment 200A operates in the non-contact mode, the distance between the probe tip 222 and the surface of the wafer W may be several hundred angstroms or more. At a distance of several hundred angstroms, an attractive force may be dominant between the probe tip 222 and the surface of the wafer W. In the non-contact mode, the probe tip 222 may be a hard probe tip. The probe tip 222, implemented as the hard probe tip, may be used to prevent contact between the probe tip 222 and the surface of the wafer W due to the attractive force. The non-contact mode may have lower resolution and higher scanning speed than the contact mode.

In the tapping mode, the probe tip 222 may vibrate on the wafer W to generate short intermittent contact, which may reduce or minimize damage to the wafer W due to the contact between the probe tip 222 and the wafer W. In the tapping mode, operation of the probe tip 222 may prevent or minimize the damage to the wafer W by sensing the wafer W according to a constant vibration applied to the probe tip 222. For example, a deviation in the constant vibration applied to the probe tip 222 may indicate contact between the probe tip 222 and the wafer W, and the probe tip 222 may be moved away from the wafer W. In addition, the tapping mode may provide a similar level of resolution as the contact mode, even when a structure with a large height difference is formed on the surface of the wafer W. Hereinafter, a case in which the AFM equipment 200A operates in the tapping mode will be described as an example.

A support unit 201 capable of supporting the wafer W may be provided by the AFM equipment 200A. The support unit 201 may fix a position of the wafer W, and may change the position of the wafer W by moving in a first direction X, a second direction Z, and/or a third direction Y as needed. In addition, the support unit 201 may be configured to be rotatable in at least one of the first direction X, the second direction Z, or the third direction Y as needed. As the support unit 201 is configured to be rotatable in at least one of the first direction X, the second direction Z, or the third direction Y, it may be possible to more precisely inspect the surface of the wafer W, which may have irregularities in three dimensions due to the particles.

A measurement unit 220 including a cantilever 221 capable of scanning the wafer W and a probe tip 222 disposed at a first end of the cantilever 221 may be provided above the support unit 201. The probe tip 222 may be formed on a lower side of the first end of the cantilever 221 or may also be fixed to the first end of the cantilever 221. For example, the cantilever 221 may be a plate-shaped spring that may be bent by a small force of the order of about several nanonewtons (nN). An end of the probe tip 222 may be machined to a size of about several atoms using nanotechnology.

The probe tip 222 may interact with the surface of the wafer W to be inspected to cause an attractive and/or a repulsive force, which may deform the cantilever 221. For example, the attractive force may be caused by van der Waals force between the probe tip 222 and the surface of the wafer W. Alternatively, the attractive force may act between the probe tip 222 and the surface of the wafer W due to an adhesive force therebetween, and the probe tip 222 and the surface of the wafer W may be separated from each other by a force greater than or equal to a pull-off force. When the attractive and repulsive forces between the probe tip 222 and the surface of the wafer W to be inspected are removed, the cantilever 221 may be restored to an original, non-deformed, shape.

A second end of the cantilever 221, opposite to the first end, may be coupled to an actuator 216. The actuator 216 may apply a vibration to the cantilever 221. The actuator 216 may be a piezoelectric actuator or a thermal actuator. The piezo actuator may be an actuator using a piezo material, which may exhibit displacement changes when a voltage is applied thereto. The thermal actuator may be an actuator using a bimetal structure, which may exhibit displacement changes due to a bimetal effect when a voltage is applied to materials with different coefficients of thermal expansion (CTEs).

FIG. 3 and FIG. 4 illustrate an example embodiment in which a second end of the cantilever 221 may be coupled to the actuator 216. Further, the support unit 201 may perform a function of such an actuator. In addition, FIG. 3 and FIG. 4 illustrate an example embodiment including a cantilever 221 and a probe tip 222, but one or more cantilevers 221 and one or more probe tips 222 may each be provided. For example, one cantilever may mount two probe tips.

The light source unit 290 may generate a laser beam through oscillation. The light source unit 290 may irradiate light to a reflection unit 215 provided at an upper side of the first end of the cantilever 221. In this case, the light irradiated to the reflection unit 215 may be, for example, laser light. More specifically, the light irradiated to the reflection unit 215 may be a Nd:YAG laser (neodymium-doped yttrium aluminum garnet laser) or a Ti:sapphire laser.

The light irradiated to the reflection unit 215 may be reflected and received by the sensing unit 230. The cantilever 221 to which the reflection unit 215 is attached may be deformed by a shape of the scanned surface, and the reflected light may amplify the deformation of the cantilever 221.

The sensing unit 230 may be, for example, a photodiode (PD). The sensing unit 230 may include photodiodes divided into multiple segments, for example, two segments or four segments, depending on the measurement method. The sensing unit 230 may amplify and detect a deflection of the cantilever 221 by sensing the laser beam.

Information sensed by the sensing unit 230 may be collected by the determination unit 260. The collected by the determination unit 260 may be used to analyze surface information of the wafer W. The determination unit 260 may generate a topographic image of the surface of the wafer W by storing a position of the measurement unit 220 in the third direction Y at different combinations of the first direction X and second direction Z coordinates on the wafer W.

In another example embodiment, when a photoresist is applied on the wafer W, the determination unit 260 may measure a level difference of the photoresist applied on the wafer W based on the information sensed by the sensing unit 230. For example, the determination unit 260 may measure a thickness of the photoresist applied on the wafer W in the third direction Y. Accordingly, the determination unit 260 may measure a thickness difference, that is, a level difference of the photoresist applied on the wafer W for each area in the third direction Y at different combinations of the first direction X and second direction Z coordinates on the wafer W. That is, the determination unit 260 may measure a thickness of the photoresist applied on the wafer W in the third direction Y.

The IR equipment 200B may include an IR source 210, an IR sensing unit 270, and an IR determination unit 280. The IR source 210 may radiate infrared light (IR) to a point on the surface of the wafer W where the probe tip 222 is positioned. For example, in order to analyze the molecular structure of the particles collected on the surface of the wafer W using infrared spectroscopy, the IR source 210 may irradiate infrared light (IR) to the particles collected on the surface of the wafer W. The infrared light generated by the IR source 210 may be tunable pulsed light. As plasmon polaritons (e.g., surface plasmon polaritons (SPPs)) excited on a sharp metal surface of the probe tip 222 are coupled to infrared light, charges may accumulate at a peak. In this case, the accumulated charges may generate a high local field. That is, by SPPs, the infrared light may travel on the surface (e.g., a metal-air interface) of the probe tip 222 and focus on the end of the probe tip 222, and the focused light may induce charges on the surface of the wafer W. The induced charges may form a dipole on the probe tip 222 and generate scattered light indicative of physical properties of the particles collected on the surface of the wafer W.

The IR sensing unit 270 may sense the scattered light, and the IR determination unit 280 may analyze the molecular structure of the particles collected on the wafer W based on the information sensed by the IR sensing unit 270.

In some example embodiments, the support unit 201 may be disposed above the coarse stage 202. The measurement unit 220 may be supported on the support frame 240. The support frame 240 and the coarse stage 202 may be electrically connected to the driving unit 250. The driving unit 250 may be configured to control a relative position of the support frame 240 and the coarse stage 202. In some example embodiments, the coarse stage 202 may move and the support frame 240 may be fixed. In some example embodiments, the coarse stage 202 may be fixed and the support frame 240 may move. In some example embodiments, both the coarse stage 202 and the support frame 240 may be configured to be movable.

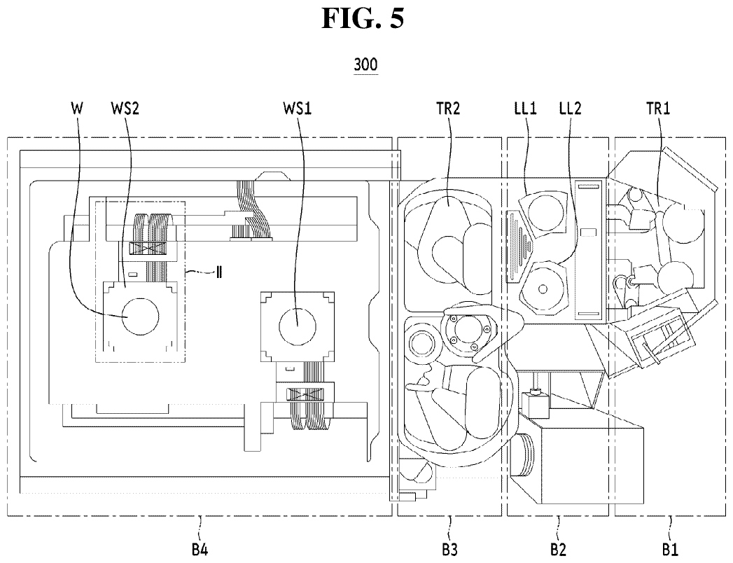

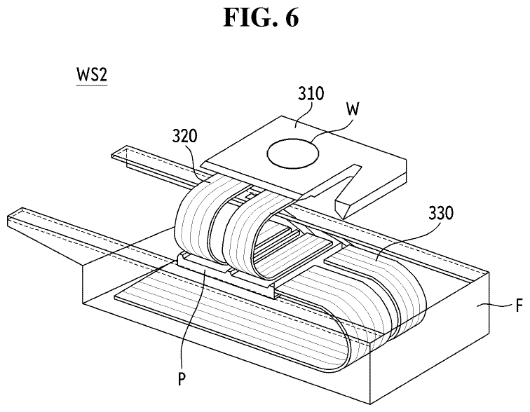

FIG. 5 is an example view for describing EUV exposure equipment. FIG. 6 is an enlarged view of section II of FIG. 5.

Referring to FIG. 5, EUV exposure equipment 300 may be an example of the semiconductor manufacturing equipment described in FIG. 1 and FIG. 2. The EUV exposure equipment 300 may be an EUV scanner. The EUV exposure equipment 300 may be divided into a plurality of areas. For example, a first area B1 may be an atmospheric wafer handling area for transferring wafers in an atmospheric pressure environment, may include a first transfer robot TR1. A second area B2 may be a load lock chamber area for transferring a wafer from the area B1, which may be an atmospheric environment, to an internal area of the EUV exposure equipment 300, which may be in a vacuum state, or transferring a wafer from the internal area of the EUV exposure equipment 300, which may be in a vacuum state, to the first area B1, which may be an atmospheric environment, may include a first load lock chamber LL1 and a second load lock chamber LL2. A third area B3 may be a vacuum wafer handling area for transferring wafers in a vacuum environment, may include a second transfer robot TR2. A fourth area B4 may be an area where wafers may be aligned and measured, and where an exposure process on the wafers may be performed. The fourth area B4 may include a first wafer stage WS1 for aligning and measuring wafers and a second wafer stage WS2 for performing an exposure process on the aligned and measured wafers.

The first to fourth areas B1 to B4 may each include at least one or more members for processing a wafer. For example, the third area B3 may include a gripper for transferring the wafer, and the fourth area B4 may include a wafer table on which the wafer may be settled for exposure, cables, or cooling lines.

The members included within an area may include different materials. For example, a plurality of members included in the fourth area B4 may include different materials. In addition, each of the members included in different areas may include a same material. For example, a member included in the third area B3 and a member included in the fourth area B4 may include the same material.

Referring to FIG. 6, the second wafer stage WS2 of the EUV exposure equipment 300 may include a wafer table 310, a first cable 320, a second cable 330, a plate P, and a frame F. The wafer table 310 may be moved to expose the wafer W in a state in which the wafer W is loaded on an upper surface thereof. A first end of the first cable 320 may be connected to the wafer table 310. A second end of the first cable 320 may be connected to the plate P. The first cable 320 may connected to the wafer table 310, and the first cable 320 may maintain a U-shaped bent state as the wafer table 310 moves. For example, the first cable 320 may not be folded. The second cable 330 may be disposed below the first cable 320. The second cable 330 may be connected to the plate P, and the second cable 330 may maintain a U-shaped bent state as the wafer table 310 moves. For example, the second cable 330 may not be folded.

The first cable 320 and the second cable 330 may each be used as a path for transmitting data. The first cable 320 and the second cable 330 may allow air and/or water to pass through the wafer table 310. The first cable 320 and the second cable 330 may include a flexible material. For example, outer shells of the first cable 320 and the second cable 330 may include a fluorine (F)-based material. The frame F may be a frame for supporting elements constituting the second wafer stage WS2, which may include the first cable 320, the plate P, and the second cable 330.

In this way, when the wafer W is introduced into the fourth area B4 through the first and second transfer robots TR1 and TR2, loaded on the wafer table 310, and an process exposure is performed, friction may occur between at least one of the first and second transfer robots TR1 and TR2 and at least one of the first and second cables 320 and 330. Alternatively, friction may occur between at least one of the first and second transfer robots TR1 and TR2 and at least one of the cooling lines provided inside each of the second cable 330 cables 320 and 330. The members from which the friction occurs may partially wear, and particles may be generated accordingly. The generated particles may scatter inside the EUV exposure equipment 300, float in the internal space, and be collected on the wafer W.

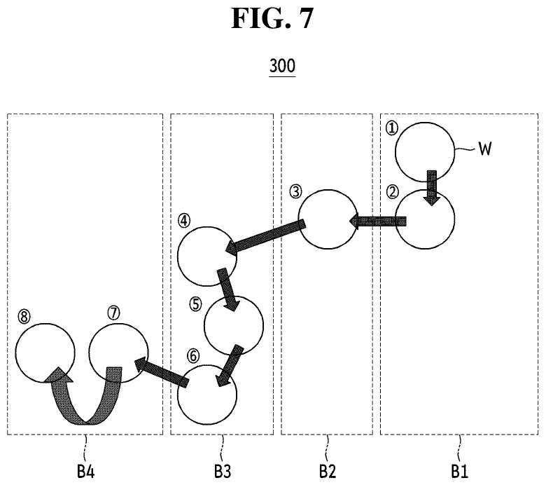

FIG. 7 is an example view for describing a plurality of areas of the EUV exposure equipment of FIG. 5.

FIG. 7 is a view illustrating a movement path of the wafer W introduced into the EUV exposure equipment 300. However, the movement path of the wafer W illustrated in FIG. 7 is illustrated as an example, and an actual movement path of the wafer W inside the EUV exposure equipment 300 may vary depending on an implementation.

Referring to FIG. 7, the wafer W introduced into the EUV exposure equipment 300 may be passed through steps “1” and “2” by the first transfer robot TR1 (illustrated in FIG. 5) in an atmospheric pressure environment of the first area B1, and may be introduced into the first load lock chamber LL1 (illustrated in FIG. 5) in the second area B2 for step “3”. Thereafter, the wafer W may be sequentially passed through steps “4”, “5”, and “6” by the second transfer robot TR2 (illustrated in FIG. 5) in the vacuum environment of the third area B3, may be instrumented at step “7” on the first wafer stage WS1 (illustrated in FIG. 5) in the fourth area B4, and may be exposed at step “8” on the second wafer stage WS2 (illustrated in FIG. 5).

When a production wafer is introduced into the EUV exposure equipment 300 to manufacture a semiconductor device, particles may be collected on the wafer by passing through the steps “1” to “8”. When the test wafer is introduced into the EUV exposure equipment 300 to analyze the molecular structure of the particles collected on the wafer, particles may also be collected on the test wafer by passing through one or more of the steps “1” to “8”. For example, when more particles are collected on the wafer W when the wafer W is exposed to processes of the steps “1” to “6” of the first area B1 to the third area B3 as compared to when the wafer W is exposed to processes of the steps “1” to “3” of the first area B1 and the third area B2, it may be estimated that wear has occurred in the member(s) included in the third area B3. Accordingly, the particles may be collected on the test wafer by repeating the processes of steps “4” to “6” of the third area B3 multiple times. For example, the processes of steps “4” to “6” may be repeated dozens of times, and the particles may be collected on the wafer may be aggregated over the iterations. In this way, the molecular structure of the particles may be analyzed by introducing the wafer on which the particles are aggregated in an area into the AFM-IR equipment 200 (illustrated in FIG. 3). By comparing the molecular structure of the particles and the molecular structure of the materials included in each member included in the third area B3, based on the analysis results, it may be possible to identify which of the members included in the third area B3 has been subject to wear or has worn.

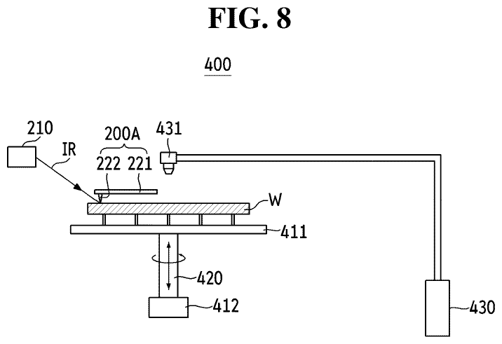

FIG. 8 is an example diagram for describing a photoresist application and soft bake process using a semiconductor spinner equipment.

Referring to FIG. 8, the semiconductor spinner equipment 400 may include a vacuum rotation chuck 411 and a driving motor 412. The semiconductor spinner equipment 400 may be provided to apply a photoresist on the wafer W before introducing the wafer W into the EUV exposure equipment 300 and performing an exposure process. The vacuum rotation chuck 411 may be a rotating plate configured to hold and rotate the wafer W. The driving motor 412 may be provided at a lower end of the vacuum rotation chuck 411 and may drive the vacuum rotation chuck 411. The driving motor 412 and the vacuum rotation chuck 411 may be connected via a support shaft 420. When the driving motor 412 rotates the support shaft 420, the vacuum rotation chuck 411 coupled to the support shaft 420 may rotate. Accordingly, the wafer W loaded on the vacuum rotation chuck 411 may rotate along with the rotation of the vacuum rotation chuck 411.

A photoresist supplied from a fluid supply unit 430 to a fluid spraying nozzle 431 may be sprayed onto the wafer W. As the wafer W rotates on the vacuum rotation chuck 411, the photoresist may be applied on an upper surface of the wafer W. Meanwhile, the AFM-IR equipment 200 (illustrated in FIG. 3) including the AFM equipment 200A and the IR source 210 may be provided together with the semiconductor spinner equipment 400. After the application of the photoresist on the wafer W is completed, the AFM-IR equipment 200 may measure a thickness of the photoresist in a vertical direction. The AFM-IR equipment 200 may remove a portion of the photoresist from a localized area by irradiating infrared light (IR) to the photoresist. The localized area may be a relatively thick area, identified based on the measurement results. Accordingly, a level difference of the photoresist applied on the wafer may be reduced and a surface of the photoresist may be flattened. For example, step S120 of FIG. 1 may include reducing a level difference of the photoresist.

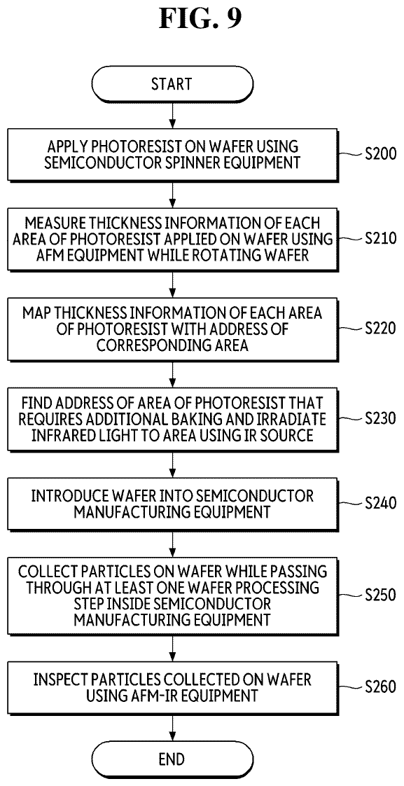

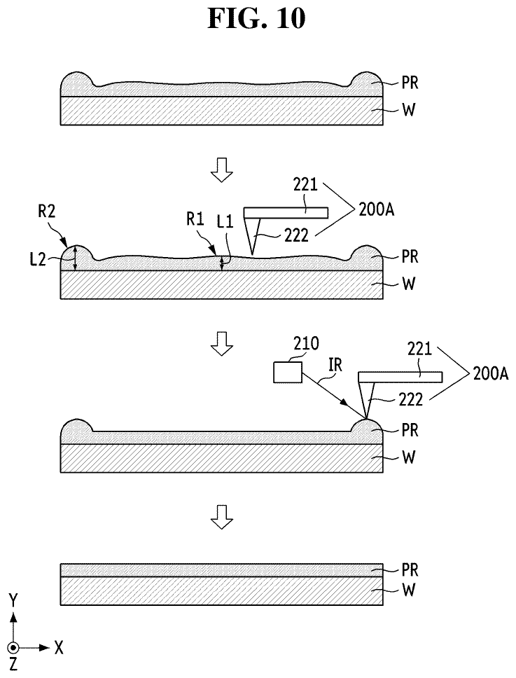

FIG. 9 is a flowchart for describing a method for inspecting a semiconductor manufacturing equipment using a wafer according to some example embodiments. FIG. 10 is an example view for describing the method of FIG. 9. Hereinafter, a method for inspecting a semiconductor manufacturing equipment using a wafer according to some example embodiments will be described with reference to FIG. 9 and FIG. 10.

Referring to FIG. 9 and FIG. 10, while rotating the wafer W using the semiconductor spinner equipment 400 (illustrated in FIG. 8), a photoresist PR may be applied on the wafer W (S200). While continuing to rotate the wafer W, thickness information of a plurality of areas of the photoresist PR applied on the wafer W may be measured using the AFM equipment 200A (S210). Referring to FIG. 3 and FIG. 4 together, the thickness of the photoresist PR may be measured based on the results of the laser light irradiated to the reflection unit 215 of the cantilever 221, reflected, and sensed by the sensing unit 230, where the reflect light sensed by the sensing unit 230 may be analyzed by the determination unit 260. In this case, the measured thickness of the photoresist PR may be a thickness of the photoresist PR measured in the third direction Y.

The thickness information of each area of the photoresist PR measured using the AFM equipment 200A and addresses of the areas are mapped (S220). For example, while rotating the wafer W using the semiconductor spinner equipment 400 and moving the AFM equipment 200A in a radial direction from the center of the wafer W, the thickness information may be obtained for each area of the photoresist PR and designated as an address.

Infrared light may be irradiated to an area that may need additional baking among the plurality of areas of the photoresist PR applied on the wafer W using the IR source 210 (S230).

The IR source 210 may irradiate infrared light to an area of the photoresist PR that has a relatively thick thickness measured in the third direction Y, based on the result of measuring a level difference of the photoresist PR measured in step S210,

For example, a second thickness L2 in the third direction Y of the second area R2 corresponding to an edge portion of the wafer W among the plurality of areas of the photoresist PR applied on the wafer W may be greater than a first thickness L1 in the third direction Y of the first area R1 corresponding to a central portion of the wafer W among the plurality of areas of the photoresist PR applied on the wafer W. In this case, by locally irradiating infrared light to the second area R2 corresponding to a relatively thick portion of the photoresist PR using the IR source 210, some of the photoresist PR in the corresponding area may be removed. Accordingly, the second thickness L2 may be reduced and the level difference of the photoresist PR applied on the wafer W may be reduced and the surface of the photoresist PR may be flattened.

The wafer W on which the photoresist PR is applied may be introduced into the semiconductor manufacturing equipment, for example, the EUV exposure equipment 300 (illustrated in FIG. 5) (S240), particles may be collected on the wafer W while passing through at least one wafer processing step inside the semiconductor manufacturing equipment (S250), and a molecular structure of the particles may be analyzed by inspecting the particles collected on the wafer W using the AFM-IR equipment 200 (S260). The steps S240 to S260 may be substantially the same as steps S100 to S120 described in connection with inspecting the semiconductor manufacturing equipment using the wafer described with reference to FIG. 1, and repetitive descriptions thereof will be omitted hereinafter.

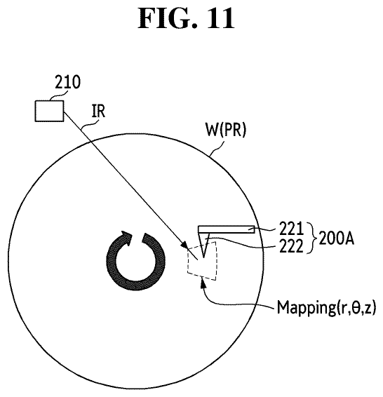

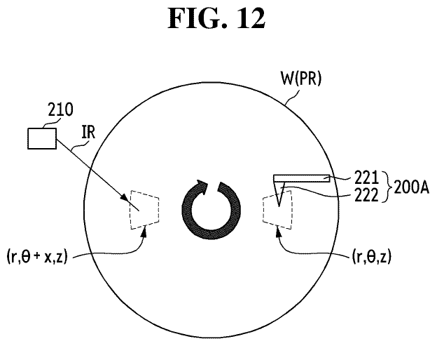

FIG. 11 and FIG. 12 are example views for describing measuring a level difference of a photoresist using an AFM-IR equipment and irradiating infrared light to the photoresist.

Referring to FIG. 11, measuring the thickness of the photoresist PR applied on the wafer W using the AFM equipment 200A in step S210 of FIG. 9 and irradiating the infrared light to the local area of the photoresist PR applied on the wafer W using the IR source 210 in step S230 may be performed at substantially a same time for each area of photoresist PR. For example, as illustrated in FIG. 11, a thickness of a specific area of the photoresist PR applied on the rotating wafer W may be measured using the AFM equipment 200A, and infrared light (IR) may be irradiated to the corresponding area using the IR source 210 based on the measured results. As illustrated in FIG. 11, the local area may be mapped to coordinates (r,θ,z), where r is a radius from an axis of rotation of the wafer, θ is an angle of the radius, and z is a thickness of the photoresist PR. Thereafter, a process of measuring a thickness of another area of the photoresist PR by moving the AFM equipment 200A and irradiating infrared light using the IR source 210 to the corresponding area based on the measured results may be repeated. The movement of the AFM equipment 200A and irradiating infrared light using the IR source 210 to an area may be a relative change, for example, where the wafer is rotating below with the AFM equipment 200A and irradiating infrared light using the IR source 210. For example, the AFM equipment 200A may be moved laterally perpendicular relative to an axis of rotation of the wafer, such that the AFM equipment 200A may make measurements at the plurality of areas. Similarly, the IR source 210 may be moved or aimed along the lateral direction perpendicular to the axis of rotation of the wafer and may target different areas of the plurality of areas.

Referring to FIG. 12, according to example embodiments, a thickness of a first area of the photoresist PR may be measured using AFM equipment 200A, and at substantially the same time, infrared light may be irradiated to a second area of the photoresist PR that is different from the first area using the IR source 210. As illustrated in FIG. 12, the second area may be mapped to coordinates (r,θ+x,y), which include the polar coordinates (r,θ) and the Cartesian coordinates (x,y) corresponding to an area previously measured using AFM equipment 200A. In this way, by separating a position where the thickness of the photoresist PR is measured using the AFM equipment 200A and a position of the photoresist PR where the infrared light is irradiated using the IR source 210, the time for the process may be shortened.

In another example embodiment, the thickness of the photoresist PR may be measured for a plurality of areas of the photoresist PR using the AFM equipment 200A, and thereafter, infrared light may be irradiated to one or more areas of the plurality of areas where the photoresist PR has a relatively thick thickness using the IR source 210 based on the measured results. For example, the thickness of the photoresist PR may be measured for all areas of the photoresist PR using the AFM equipment 200A, and thereafter, infrared light may be irradiated to the areas where the photoresist PR has a relatively thick thickness using the IR source 210 based on the measured results. Similarly, the measurement and irradiation may be performed for blocks of the areas, or another sub-set of the plurality of areas.

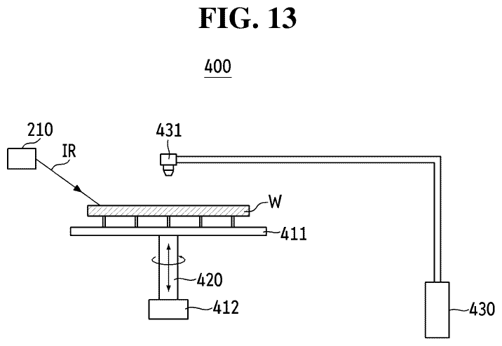

FIG. 13 is a view for describing a method for inspecting a semiconductor manufacturing equipment using a wafer according to still some other example embodiments.

Referring to FIG. 13, after applying the photoresist on the wafer W using the semiconductor spinner equipment 400 before performing the exposure process on the wafer W, infrared light may be irradiated to the photoresist applied on the wafer W using the IR source 210, without measuring the level difference of the photoresist using the AFM equipment 200A when baking the photoresist. For example, the infrared light may be irradiated using the IR source 210 to an edge portion of the photoresist where an edge bead may be expected to occur when the photoresist is applied on the wafer W, without measuring the thickness of the photoresist.

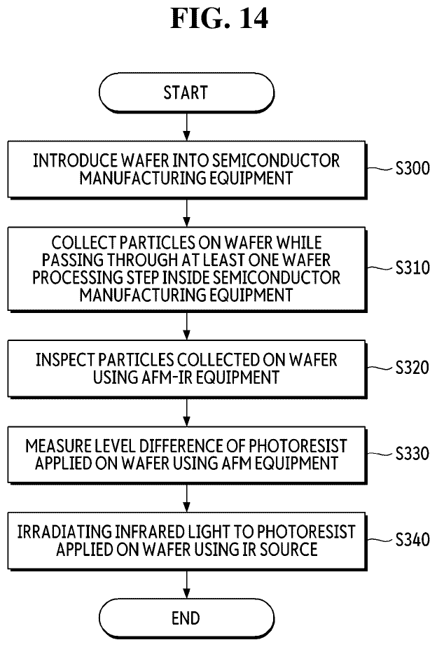

FIG. 14 is a flowchart for describing a method for inspecting a semiconductor manufacturing equipment using a wafer according to still some other example embodiments.

Referring to FIG. 14, a wafer may be introduced into the semiconductor manufacturing equipment, for example, the EUV exposure equipment 300 (illustrated in FIG. 5) (S300), particles may be collected on the wafer while passing through at least one wafer processing step inside the semiconductor manufacturing equipment (S310), and a molecular structure of the particles may be analyzed by inspecting the particles collected on the wafer using the AFM-IR equipment 200 (illustrated in FIG. 3) (S320). The description of steps S300 to S320 may be substantially the same as steps S100 to S120 described in connection with inspecting the semiconductor manufacturing equipment using the wafer described with reference to FIG. 1, and repetitive descriptions therefore will be omitted hereinafter.

Subsequently, the wafer may be introduced into the semiconductor spinner equipment 400 (illustrated in FIG. 8). Thereafter, a level difference of the photoresist applied on the wafer may be measured using the AFM equipment 200A (S330). In this case, the level difference of the photoresist and a degree of chemical bonding in each area of the photoresist may be measured using AFM equipment 200A. Subsequently, based on the results of measuring characteristics of each area of the photoresist applied on the wafer, such as the degree of chemical bonding in each area, infrared light may be irradiated to a local area of the photoresist (S340).

For example, as a result of inspecting the characteristics of the photoresist applied on the wafer using AFM equipment 200A after exposure, if the degree of chemical bonding in a first area of the photoresist is relatively weak, infrared light may be locally irradiated to the first area using the IR source 210 in a post exposure bake (PEB) process.

Alternatively, as a result of measuring the level difference (i.e., thickness of each area of the photoresist) of the photoresist applied on the wafer using the AFM equipment 200A after exposure, if a second area of the photoresist is thicker than other areas, infrared light may be locally irradiated to the second area using the IR source 210 in the PEB process. Accordingly, a surface of the photoresist applied on the wafer may be flattened.

As described with reference to FIG. 12, an area where the level difference of the photoresist applied on the wafer may be measured using the AFM equipment 200A after exposure to the wafer and an area where the infrared light is irradiated to the photoresist applied on the wafer using the IR equipment 200B may be separated from each other. For example, the AFM equipment 200A and the IR equipment 200B may be operated in parallel on different areas of the wafer.

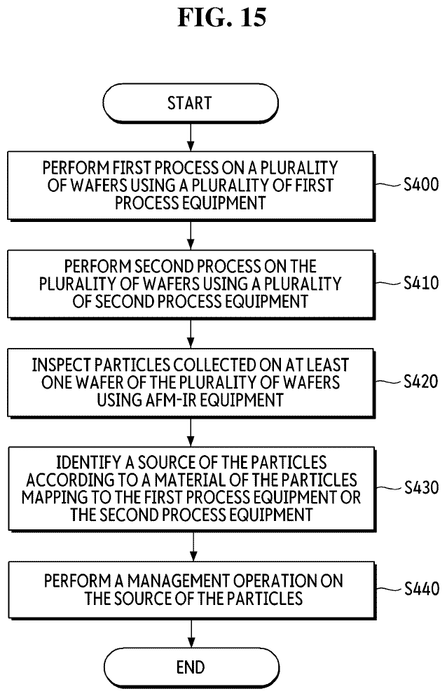

FIG. 15 is a flowchart for describing a method for inspecting a semiconductor manufacturing equipment using a wafer according to still some other example embodiments.

Referring to FIG. 15, a first process may be performed on each of a plurality of wafers using different instances of first process equipment (S400). To perform the first process for manufacturing a semiconductor device on the plurality of wafers, a plurality of first process equipment may be provided. Each of the plurality of first process equipment may process a corresponding wafer. However, depending on an example embodiment, a given instance of the first process equipment may also process two or more wafers. For example, the given instance of the first process equipment may sequentially process the two or more wafers. The plurality of first process equipment may perform a same first process on each of the plurality of wafers, but materials included in members included within each of the equipment may be different from each other. Accordingly, when the plurality of wafers complete the first process, the molecular structures of particles collected on each wafer may be different.

Subsequently, a second process may be performed on each of the plurality of wafers using different instances of second process equipment (S410). The second process may be a process for manufacturing a semiconductor device using the plurality of wafers that have passed through the first process, and may be a different process from the first process. Each of the plurality of second process equipment may process one wafer. However, depending on an example embodiment, a given instance of the second process equipment may also process two or more wafers. For example, the given instance of the second process equipment may sequentially process the two or more wafers. The plurality of second process equipment may perform a same second process on each of the plurality of wafers, but materials included in members included within each of the equipment may be different from each other. Accordingly, when the plurality of wafers completes the second process, the molecular structures of particles collected on each wafer may be different.

Subsequently, for at least one wafer among the plurality of wafers on which the second process has been completed, particles collected on the wafer may be inspected using the AFM-IR equipment 200 (illustrated in FIG. 3) (S420). A method for analyzing the molecular structure of the particles collected on a wafer using the AFM-IR equipment 200 is described elsewhere herein, and a repetitive description therefore be omitted hereinafter.

In the above, it has been described that the wafers pass through the first process and the second process, but example embodiments are not limited thereto. Depending on an example embodiment, a plurality of wafers may pass through a process of three or more steps, particles collected on at least one wafer may be inspected using the AFM-IR equipment 200, and for a plurality of wafers that pass through a process of at least one step, particles collected on at least one wafer may be inspected using the AFM-IR equipment 200.

In this way, in the step-by-step process of manufacturing a semiconductor device using a production wafer, when the particles collected on wafers that pass through the process are inspected using the AFM-IR equipment 200 and the molecular structure of the particles is analyzed, a process equipment from which the particles originated may be identified (S430). Once the process equipment from which the particles originated is identified, the test wafer may be introduced into the process equipment according to the method described with reference to FIGS. 1 to 4, the particles may be collected on the test wafer while passing through at least one wafer process step inside the corresponding equipment, and the collected particles may be then inspected using the AFM-IR equipment 200, to confirm which of the internal members of the process equipment the particles originated from. Accordingly, it may be possible to identify, specifically, which of the members inside the equipment is a source of the particles. Accordingly, it is possible to manage a lifespan of the corresponding member where wear is occurring or has occurred (S440). For example, the corresponding member identified as a source of the particles may be serviced or replaced.

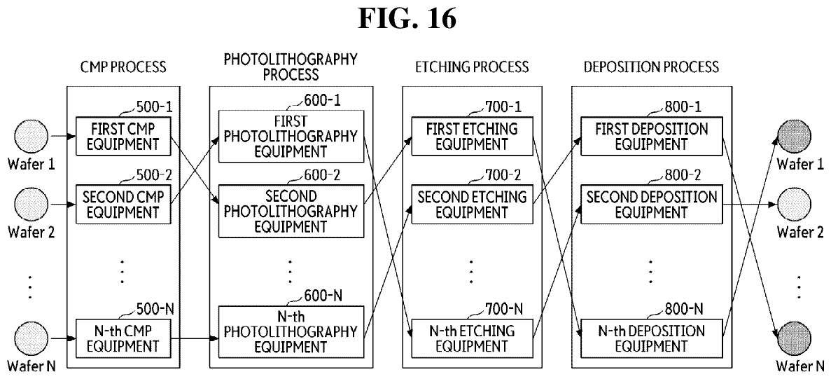

FIG. 16 is an example view for describing the method of FIG. 15.

Referring to FIG. 16, a plurality of wafers Wafer1 to WaferN (where N is an integer greater than 1) may pass through a chemical mechanical polishing (CMP) process, a photolithography process, an etching process, and a deposition process. A plurality of CMP equipment 500-1 to 500-N may be provided to perform the CMP process on each of the plurality of wafers Wafer1 to WaferN. Each instance of the CMP equipment 500-1 to 500-N may perform the CMP process on a corresponding wafer, but materials included in the members included within each equipment may be different from each other. For example, the members included in a first CMP equipment 500-1 and the members included in a second CMP equipment 500-2 may include different materials. Each of the plurality of wafers Wafer1 to WaferN may be introduced into any one of the plurality of CMP equipment 500-1 to 500-N and may pass through the CMP process. In this case, which instance of the CMP equipment 500-1 to 500-N each of the wafers Wafer to WaferN will be introduced into may be randomly determined.

In a following step, the plurality of wafers Wafer1 to WaferN that pass through the CMP process may be randomly introduced into any one of different photolithography equipment 600-1 to 600-N. Likewise, the plurality of wafers Wafer1 to WaferN that pass through the photolithography process may be randomly introduced into any instance of the etching equipment 700-1 to 700-N, and thereafter, the plurality of wafers Wafer1 to WaferN for which the etching process has been completed may be randomly introduced into any instance of the deposition equipment 800-1 to 800-N.

Each instance of photolithography equipment 600-1 to 600-N may perform the photo process on the wafer, but materials included in the members included within different instances of the photolithography equipment 600-1 to 600-N may be different from each other. Likewise, the members included within different instances of the etching equipment 700-1 to 700-N may include different materials, and the members included within different instances of the deposition equipment 800-1 to 800-N may include different materials.

For at least one wafer of the plurality of wafers on which the deposition process has been completed, the molecular structure of the particles collected on the wafer may be analyzed using the AFM-IR equipment 200 (illustrated in FIG. 3). For example, as a result of analyzing the molecular structure of particles collected on the wafer Wafer1 that have passed through a first CMP equipment 500-1, a second photolithography equipment 600-2, a first etching equipment 700-1, and an N-th deposition equipment 800-N, it may be assumed that the particle material originated from one or more of the first CMP equipment 500-1, the second photolithography equipment 600-2, the first etching equipment 700-1, and the N-th deposition equipment 800-N.

In this case, after the test wafer is introduced into the corresponding equipment and the particles may be collected again on the wafer while processing at least one wafer inside the corresponding equipment, the particles collected on the wafer may be inspected using the AFM-IR equipment 200. Accordingly, the members inside the corresponding equipment that have worn may be identified according to the particles collected on the wafer, and when the estimated degree of wearing of the member is severe, the lifespan of the corresponding member may be managed by replacing the corresponding member.

In this way, when a large number of particles are found to be collected on the wafer that has passed through a plurality of process steps, the molecular structure of the particles may be analyzed using the AFM-IR equipment 200, and defective process equipment may be traced back based on the analysis results. As a result, a search range for finding the defective process equipment may be reduced.

Although embodiments of the present disclosure have been described with reference to the accompanying drawings, embodiments of the present disclosure are not limited thereto, but may be implemented in various different forms. A person skilled in the art may appreciate that the present disclosure may be practiced in other concrete forms without changing the technical spirit or essential characteristics of the present disclosure. Therefore, it should be appreciated that embodiments as described herein are not restrictive, but are illustrative in all respects.

What is claimed is:

1. A method for inspecting a semiconductor manufacturing equipment using a wafer, the method comprising:
introducing the wafer into the semiconductor manufacturing equipment;
passing the wafer through at least one wafer processing step inside the semiconductor manufacturing equipment, wherein particles generated by the at least one wafer processing step are collected on the wafer; and
inspecting the particles collected on the wafer with an atomic force microscope (AFM),
wherein the inspecting of the particles collected on the wafer with the AFM includes irradiating infrared light to the particles collected on the wafer using an infrared ray (IR) source to identify the particles.

2. The method of claim 1, wherein the wafer includes a photoresist applied on the wafer, the method further comprising:
measuring a level difference of the photoresist applied on the wafer using the AFM; and
reducing the level difference of the photoresist applied on the wafer using the IR source.

3. The method of claim 1, wherein the wafer includes a photoresist applied on the wafer, and
wherein the irradiating of the infrared light to the photoresist applied on the wafer using the IR source includes irradiating infrared light to an area of the photoresist applied on the wafer corresponding to an edge portion of the wafer.

4. The method of claim 1, wherein the semiconductor manufacturing equipment is an extreme ultraviolet (EUV) exposure equipment, and
the particle collected on the wafer is generated through at least one of, inside the EUV exposure equipment,
transferring the wafer in an atmospheric pressure environment;
transferring the wafer using a load lock chamber;
transferring the wafer in a vacuum environment; and
performing an exposure process on the wafer.

5. The method of claim 4, further comprising, before the introducing of the wafer into the EUV exposure equipment,
applying a photoresist on the wafer while rotating the wafer using a semiconductor spinner equipment including a vacuum rotation chuck comprising a rotating plate configured to hold and rotate the wafer, and a driving motor configured to drive the vacuum rotation chuck wherein the infrared light is irradiated to the photoresist applied on the wafer using the IR source.

6. The method of claim 4, further comprising, after the performing of the exposure process on the wafer using the EUV exposure equipment:
applying a photoresist on the wafer; and
irradiating infrared light to the photoresist applied on the wafer while rotating the wafer using a semiconductor spinner equipment including a vacuum rotation chuck comprising a rotating plate configured to hold and rotate the wafer and a driving motor configured to drive the vacuum rotation chuck, and the IR source.

7. The method of claim 6, further comprising measuring a thickness of a first area and a thickness of a second area of the photoresist applied on the wafer using the AFM, wherein the irradiating of the infrared light to the photoresist applied on the wafer using the IR source includes irradiating infrared light to the first area, in response to the thickness of the first area being greater than the thickness of the second area.

8. The method of claim 6, further comprising measuring a thickness of a first area of the photoresist applied on the wafer using the AFM,
wherein the irradiating of the infrared light to the photoresist applied on the wafer using the IR source includes irradiating infrared light to a second area different from the first area among the areas of the photoresist applied on the wafer.

9. The method of claim 1, wherein the semiconductor manufacturing equipment includes a plurality of semiconductor manufacturing equipment that performs different processes, and
the plurality of semiconductor manufacturing equipment include at least one of a chemical mechanical polishing (CMP) equipment, a photolithography equipment, an etching equipment, or a deposition equipment.

10. The method of claim 1, wherein the semiconductor manufacturing equipment includes a first area for processing the wafer using a first member including a first material and processing the wafer using a second member including a second material different from the first material, and
the method further comprises:
providing a map of the first material and the second material to the first member and the second member, respectively; and
localizing a source of the particles to one of the first member or the second member based on the inspecting of the particles.

11. The method of claim 1, wherein the semiconductor manufacturing equipment includes a first area for processing the wafer using a first member including a first material and a second area for processing the wafer using a second member including a second material, and
the method further comprises:
providing a map of the first material and the second material to the first area and the second area, respectively; and
localizing a source of the particles to one of the first area or the second area based on the inspecting of the particles.

12. A method for inspecting a semiconductor manufacturing equipment, the method comprising:
performing a first process on each of a plurality of wafers using any one of a plurality of first process equipment;
performing a second process different from the first process on each of the plurality of wafers using any one of a plurality of second process equipment different than the plurality of first process equipment, wherein a particle generated by at least one of the first process and the second process is collected on a first wafer of the plurality of wafers; and
inspecting the particle collected on the first wafer on which the second process has been completed with an atomic force microscope (AFM),
wherein the inspecting of the particle collected on the first wafer with the AFM includes irradiating infrared light to the particle collected on the first wafer using an infrared ray (IR) source; and
localizing a source of the particle to one of the first process or the second process based on the inspection of the particle.

13. The method of claim 12, wherein the first process is a chemical mechanical polishing (CMP) process and the second process is a photolithography process, an etching process, or a deposition process, wherein the method further comprises performing the chemical mechanical polishing (CMP) process, the photolithography process, the etching process, and the deposition process, sequentially.

14. The method of claim 12, wherein the localizing of the source of the particle to one of the first process or the second process based on the inspection of the particle further comprises:
determining that the particle includes a same material as a first member included in a first wafer processing equipment that performed the first process on the first wafer as a result of inspecting the particle collected on the first wafer on which the second process is completed with the AFM;
introducing a first test wafer into the first wafer processing equipment in response to the determination that the particle includes the same material as the first member included in the first wafer processing equipment that performed the first process on the first wafer;
generating a second particle by at least one wafer processing step inside the first wafer processing equipment;
collecting the second particle on the first test wafer while passing through the at least one wafer processing step inside the first wafer processing equipment; and
inspecting the second particle collected on the first test wafer with the AFM.

15. The method of claim 14, wherein the plurality of wafers further includes a second wafer, and
the method further comprises:
determining that a third particle including a same material as a second member included in a second wafer processing equipment that performed the second process on the second wafer among the plurality of second processing equipment as a result of inspecting the third particle collected on the second wafer on which the second process is completed with the AFM;
introducing a second test wafer into the second wafer processing equipment in response to the determination that the third particle includes the same material as the second member included in the second wafer processing equipment that performed the second process on the second wafer;
generating a fourth particle by at least one wafer processing step inside the second wafer processing equipment;
collecting the fourth particle on the second test wafer while passing through the at least one wafer processing step inside the second wafer processing equipment; and
inspecting the fourth particle collected on the second test wafer with the AFM.

16. A method for inspecting a semiconductor manufacturing equipment using a wafer, the method comprising:
introducing the wafer into an extreme ultraviolet (EUV) exposure equipment, wherein a particle is generated by the EUV exposure equipment;
collecting the particle on the wafer while passing through at least one wafer processing step among a plurality of wafer processing steps inside the EUV exposure equipment; and
inspecting the particle collected on the wafer with an atomic force microscope (AFM),
wherein the plurality of wafer processing steps inside the EUV exposure equipment include:
transferring the wafer in an atmospheric pressure environment;
transferring the wafer using a load lock chamber;
transferring the wafer in a vacuum environment; and
performing an exposure process on the wafer, and
the inspecting of the particle collected on the wafer with the AFM includes irradiating infrared light to the particle collected on the wafer using an infrared ray (IR) source to identify the particle.

17. The method of claim 16, further comprising, before the introducing of the wafer into the EUV exposure equipment,
applying a photoresist on the wafer while rotating the wafer using a semiconductor spinner equipment including a vacuum rotation chuck comprising a rotating plate configured to hold and rotate the wafer, and a driving motor configured to drive the vacuum rotation chuck;
measuring a level difference of the photoresist applied on the wafer using the AFM; and
irradiating infrared light to the photoresist applied on the wafer using the IR source based on a result of measuring the level difference of the photoresist.

18. The method of claim 17, wherein the irradiating of the infrared light to the photoresist applied on the wafer using the IR source includes irradiating infrared light to a first area of the wafer, in response to a thickness of the first area of the photoresist applied on the wafer being greater than a thickness of a second area, as measured using the AFM.

19. The method of claim 16, further comprising, after the performing of the exposure process on the wafer using the EUV exposure equipment:
applying a photoresist on the wafer; and
irradiating infrared light to the photoresist applied on the wafer.

20. The method of claim 19, further comprising measuring a thickness of a first area of the photoresist applied on the wafer using the AFM,
wherein the irradiating of the infrared light to the photoresist applied on the wafer using the IR source includes irradiating infrared light to a second area different from the first area among the areas of the photoresist applied on the wafer.
